(19) United States
(12) Patent Application Publication
(10) Pub. No.: US 2014/0061749 A1
(43) Pub. Date: Mar. 6, 2014

(54) TRANSPARENT NON-VOLATILE MEMORY DEVICES AND METHODS OF MANUFACTURING THE SAME

(71) Applicant: ELECTRONICS AND TELECOMMUNICATIONS RESEARCH INSTITUTE, Daejeon (KR)

(72) Inventor: Rae-Man PARK, Daejeon (KR)

(73) Assignee: Electronics and Telecommunications Research Institute, Daejeon (KR)

(21) Appl. No.: 13/717,785

(22) Filed: Dec. 18, 2012

(30) Foreign Application Priority Data
Sep. 6, 2012 (KR) 10-2012-0098930

(51) Int. Cl. H01L 29/792; H01L 29/66

(52) U.S. Cl. CPC H01L 29/792; H01L 29/66833
USPC 257/314; 438/287

(57) ABSTRACT

Disclosed are transparent non-volatile memory devices and methods of manufacturing the same. The method may include forming an active layer on a substrate, forming a source and a drain spaced apart from each other on the active layer, forming a gate insulating layer having quantum dots on the source, the drain, and the active layer, and forming a gate on the gate insulating layer between the source and the drain. The quantum dots and the gate insulating layer may be formed simultaneously.

### CROSS-REFERENCE TO RELATED APPLICATIONS

This U.S. non-provisional patent application claims priority under 35 U.S.C. §119 to Korean Patent Application No. 10-2012-0098930, filed on Sep. 6, 2012, the entirety of which is incorporated by reference herein.

### BACKGROUND

The inventive concept relates to semiconductor devices and methods of manufacturing the same, more particularly, to transparent non-volatile memory devices and methods of manufacturing the same.

Recently, various researches are conducted for a metal oxide semiconductor. The metal oxide semiconductor may be widely used in transparent electronic devices. The transparent electronic devices may have high optical characteristics as well as excellent electrical characteristics. The transparent electronic devices may include a thin film transistor.

The transparent thin film transistor may have transparent electrodes, an active layer, and a transparent insulating layer. The active layer and the insulating layer may be mostly formed of an oxide. When the thin film transistor includes a floating gate, the electronic device may be realized as a non-volatile memory device. The floating gate may store tunneling charges passing through the insulating layer.

The metal oxide semiconductor may be formed at a temperature of about 300 degrees Celsius or less. The metal oxide semiconductor may include metal nano particles. The metal nano particles may store the tunneling charges. The metal nano particles may be formed by a high temperature thermal annealing process of about 500 degrees Celsius. However, the high temperature thermal annealing process may cause bad non-volatile memory devices.

### SUMMARY

Embodiments of the inventive concept may provide transparent non-volatile memory devices capable of improving productivity and methods of manufacturing the same.

Embodiments of the inventive concept may also provide transparent non-volatile memory devices capable of improving production yield and methods of manufacturing the same.

In one aspect, a transparent non-volatile memory device may include: a substrate; an active layer disposed on the substrate; a source and a drain spaced apart from each other on the active layer; a gate insulating layer covering the source, the drain, and the active layer; and a gate disposed on the gate insulating layer between the source and the drain. Here, the gate insulating layer may include a silicon nitride layer having quantum dots; and the quantum dots may store charges injected from the active layer into the gate insulating layer by an electric field generated between the gate and the active layer.

In an embodiment, the quantum dots may include silicon nano particles.

In an embodiment, each of the silicon nano particles may have a particle size within a range of about 3 nm to about 7 nm.

In an embodiment, a number density of the silicon nano particles in the gate insulating layer may have a range of about 10¹⁶ ea/cm³ to about 10¹⁸ ea/cm³.

In an embodiment, the gate insulating layer may have a transmittance of about 90% or more.

In an embodiment, the source, the drain, and the gate may include a transparent metal.

In an embodiment, the transparent metal may include indium-tin oxide (ITO) and/or indium-zinc oxide (IZO).

In an embodiment, the active layer may include a transparent metal oxide layer.

In an embodiment, the transparent metal oxide layer may include titanium oxide and/or indium-titanium oxide.

In another aspect, a method of manufacturing a transparent non-volatile memory device may include: forming an active layer on a substrate; forming a source and a drain spaced apart from each other on the active layer; forming a gate insulating layer having quantum dots on the source, the drain, and the active layer; and forming a gate on the gate insulating layer between the source and the drain. The quantum dots and the gate insulating layer may be formed simultaneously.

In an embodiment, the gate insulating layer may be formed by a plasma enhanced-chemical vapor deposition (PE-CVD) process.

In an embodiment, a silane gas and a nitrogen gas may be used as a source gas and a reaction gas of the PE-CVD process, respectively.

In an embodiment, a mixture ratio of the silane gas to the nitrogen gas may be within a range of about 1:1000 to about 1:4000 in the PE-CVD process.

In an embodiment, a silane gas and an ammonia gas may be used as a source gas and a reaction gas of the PE-CVD process, respectively.

In an embodiment, a mixture ratio of the silane gas to the ammonia gas may be within a range of about 1:1 to about 1:5 in the PE-CVD process.

### BRIEF DESCRIPTION OF THE DRAWINGS

The inventive concept will become more apparent in view of the attached drawings and accompanying detailed description.

FIG. 1 is a cross-sectional view illustrating a transparent non-volatile memory device according to embodiments of the inventive concept;

FIG. 2 is a graph illustrating a transmittance according to wavelength variation of a visible ray;

FIG. 3 is a capacitance-voltage (C-V) graph of a gate insulating layer according to embodiments of the inventive concept;

FIGS. 4 to 7 are cross-sectional views illustrating a method of manufacturing a transparent non-volatile memory device according to embodiments of the inventive concept; and

FIG. 8 is a schematic diagram illustrating a chemical vapor deposition apparatus.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

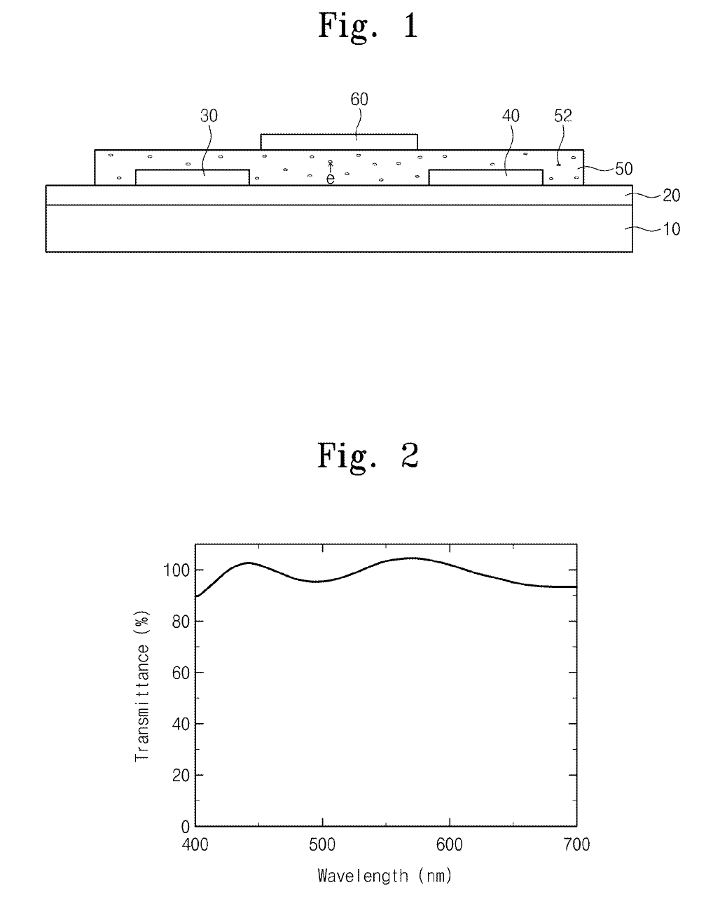

FIG. 1 is a cross-sectional view illustrating a transparent non-volatile memory device according to embodiments of the inventive concept.

Referring to FIG. 1, a transparent non-volatile memory device according to embodiments may include a substrate 10, an active layer 20, a source 30, a drain 40, a gate insulating layer 50, and a top gate 60.

The substrate 10 may include a transparent substrate or a flexible substrate. The transparent substrate may be a glass substrate. The flexible substrate may be a transparent plastic substrate.

The active layer 20 may include a transparent metal oxide layer. The transparent metal oxide layer may have a visible ray transmittance of about 80% or more. The transparent metal oxide layer may include titanium oxide and/or indium-titanium oxide. Alternatively, the transparent metal oxide layer may be formed of a metal oxide including indium or zinc and having a low electron concentration of about 1×10¹⁸/cm³ or less.

The source 30 and the drain 40 may be disposed to be spaced apart from each other on the active layer 20. The source 30, the drain 40, and the top gate 60 may be transparent electrodes. The transparent electrodes may include indium-tin oxide (ITO) and/or indium-zinc oxide (IZO) having a high electron concentration of about 1×10¹⁹/cm³ or more.

The gate insulating layer 50 may cover the active layer 20, the source 30, and the drain 40. The gate insulating layer 50 may include a dielectric layer such as a silicon oxide layer and/or a silicon nitride layer.

The top gate 60 may be disposed on the gate insulating layer 50 between the source 30 and the drain 40. The top gate 60 may include a transparent metal. FIG. 1 illustrates the transparent non-volatile memory device having a top gate structure. However, the inventive concept is not limited thereto. For example, the transparent non-volatile memory device according to embodiments may have a bottom gate structure.

The gate insulating layer 50 may have quantum dots 52. The quantum dots 52 may include silicon nano particles. Each of the quantum dots 52 may have a particle size within a range of about 1 nm to about 10 nm. More particularly, each of the quantum dots 52 may have a particle size within a range of about 3 nm to about 7 nm. The quantum dots 52 distributed in the gate insulating layer 50 may have a number density within a range of about 10¹⁶ ea/cm³ to about 10¹⁸ ea/cm³. A transmittance of the gate insulating layer 50 will be described with reference to FIG. 2.

FIG. 2 is a graph illustrating a transmittance according to wavelength variation of a visible ray.

Referring to FIGS. 1 and 2, the gate insulating layer 50 may have a visible ray transmittance of about 90% or more. Here, the gate insulating layer 50 is a silicon nitride layer having a thickness of about 200 nm. Generally, a silicon nitride layer may have a transmittance of about 80% or more. The quantum dots 52 may be formed to hardly influence the transmittance of the gate insulating layer 50.

Thus, the transparent non-volatile memory device according to embodiments may be used as a transparent electronic device.

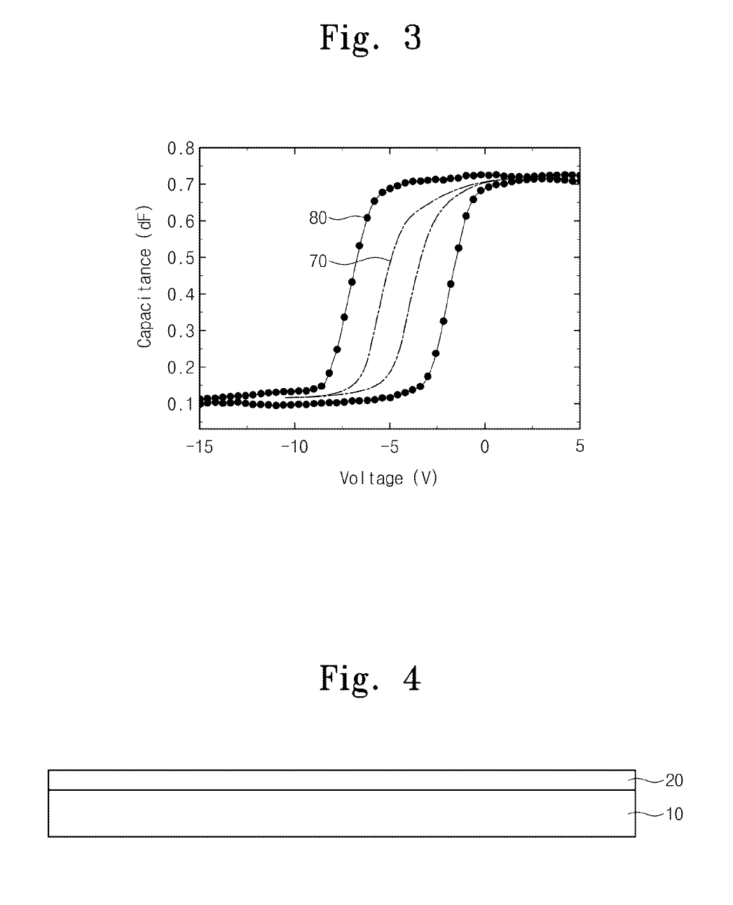

The quantum dots 52 may store electrons. The electrons may be injected into the gate insulating layer 50 from the active layer 20 by a tunneling effect. The tunneling effect may occur when drift current flows in the active layer 20 between the source 30 and the drain 40 and an electric field generated between the active layer 20 and the top gate 60 is greater than a predetermined level. Thus, the quantum dots 52 may store data of the transparent non-volatile memory device. A capacitance according to the quantum dots 52 in the gate insulating layer 50 will be described with reference to FIG. 3.

FIG. 3 is a capacitance-voltage (C-V) graph of a gate insulating layer according to embodiments of the inventive concept. The gate insulating layer 50 has a high frequency C-V profile. In the graph, a horizontal axis represents a bias voltage, and a vertical axis represents a capacitance. C-V values were detected from the gate insulating layer 50 between a silicon substrate and an aluminum electrode.

Here, a reference numeral “70” is a first high frequency C-V graph of a general gate insulating layer, and a reference numeral “80” is a second high frequency C-V graph of the gate insulating layer 50 having the quantum dots 52. The second high frequency C-V graph 80 may have greater hysteresis than the first high frequency C-V graph 70. This is because the hysteresis increases by the quantum dots 52.

A method of manufacturing the transparent non-volatile memory device described above will be described with reference to FIGS. 4 to 7.

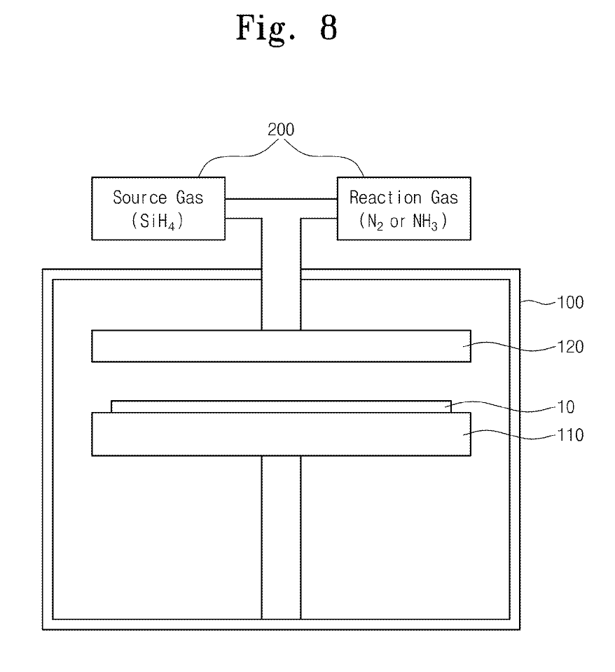

FIGS. 4 to 7 are cross-sectional views illustrating a method of manufacturing a transparent non-volatile memory device according to embodiments of the inventive concept. FIG. 8 is a schematic diagram illustrating a chemical vapor deposition apparatus for depositing a gate insulating layer 50 illustrate in FIG. 6.

Referring to FIG. 4, an active layer 20 is formed on a substrate 10. The active layer 20 may be formed by a sputtering process. The active layer 20 may include a metal oxide having a low electron concentration of about 1×10¹⁸/cm³ or less.

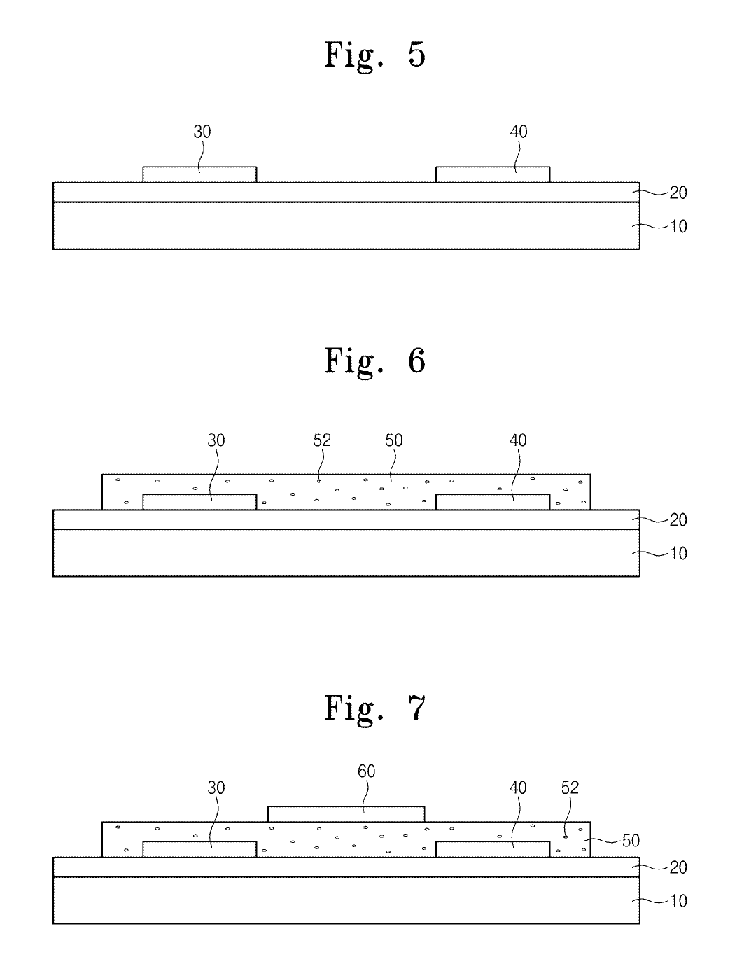

Referring to FIG. 5, a source 30 and a drain 40 are formed on the active layer 20. The source 30 and the drain 40 may be formed by a depositing process, a photolithography process, and an etching process. The depositing process may include a sputtering process.

Referring to FIG. 6, a gate insulating layer 50 is formed on the source 30, the drain 40, and the active layer 20. The gate insulating layer 50 may be formed by a plasma enhanced-chemical vapor deposition (PE-CVD) process. The PE-CVD process will be described in detail with reference to FIG. 8.

The gate insulating layer 50 may be formed by chemical reaction of a source gas and a reaction gas. The source gas may include a silane (SiH₄) gas. The reaction gas may include a nitrogen (N₂) gas or an ammonia (NH₃) gas. The substrate 10 may be supported by a chuck 110. A gas supplying part 200 supplies the source gas and the reaction gas into a chamber 100. A showerhead 120 may mix the source gas and the reaction gas in a plasma state and then jet the mixed gas to the substrate 10.

According to some embodiments of the inventive concept, the silane gas and the nitrogen gas may be supplied into the chamber 100 in the PE-CVD process. At this time, a mixture ratio of the silane gas to the nitrogen gas may be within a range of about 1:1000 to about 1:4000. In this case, the silicon nitride layer may be deposited on the substrate 10 at a growth rate within a range of about 1.3 nm/min to about 1.8 nm/min At this time, the quantum dots 52 may be formed in the silicon nitride layer. For example, the quantum dots 52 may include silicon nano particles. Each of the silicon nano particles may have a particle size within a range of about 3 nm to about 7 nm. A number density of the silicon nano particles in the silicon nitride layer may have a range of about 10¹⁶ ea/cm³ to about 10¹⁸ ea/cm³.

According to other embodiments of the inventive concept, the silane gas and the ammonia gas may be supplied into the chamber 100 in the PE-CVD process. At this time, a mixture ratio of the silane gas to the ammonia gas may be within a range of about 1:1 to about 1:5. In this case, the silicon nitride layer may be deposited on the substrate 10 at a growth rate within a range of about 5 nm/min to about 10 nm/min The quantum dots 52 may be formed in the gate insulating layer 50 without an additional thermal annealing process and/or an additional patterning process.

Thus, it is possible to improve productivity and production yield of the transparent non-volatile memory device by the manufacturing method according to embodiments of the inventive concept.

Referring to FIG. 7, a top gate 60 is formed on the gate insulating layer 50 between the source 30 and the drain 40. The top gate 60 may be formed by a depositing process, a photolithography process, and an etching process. The top gate 60 may include ITO and/or IZO. The depositing process for the top gate 60 may include a sputtering process.

According to embodiments of the inventive concept, the transparent non-volatile memory device may have the active layer, the source, the drain, the gate insulating layer, and the top gate. The gate insulating layer may have the quantum dots. The quantum dots and the gate insulating layer may be formed simultaneously by the PE-CVD process.

Thus, it is possible to improve the productivity and production yield of the transparent non-volatile memory devices.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A transparent non-volatile memory device comprising:
a substrate;
an active layer disposed on the substrate;
a source and a drain spaced apart from each other on the active layer;
a gate insulating layer covering the source, the drain, and the active layer; and
a gate disposed on the gate insulating layer between the source and the drain,
wherein the gate insulating layer includes a silicon nitride layer having quantum dots; and
wherein the quantum dots store charges injected from the active layer into the gate insulating layer by an electric field generated between the gate and the active layer.

2. The transparent non-volatile memory device of claim 1, wherein the quantum dots include silicon nano particles.

3. The transparent non-volatile memory device of claim 2, wherein each of the silicon nano particles has a particle size within a range of about 3 nm to about 7 nm.

4. The transparent non-volatile memory device of claim 2, wherein a number density of the silicon nano particles in the gate insulating layer has a range of about 10¹⁶ ea/cm³ to about 10¹⁸ ea/cm³.

5. The transparent non-volatile memory device of claim 1, wherein the gate insulating layer has a transmittance of about 90% or more.

6. The transparent non-volatile memory device of claim 1, wherein the source, the drain, and the gate include a transparent metal.

7. The transparent non-volatile memory device of claim 6, wherein the transparent metal includes indium-tin oxide (ITO) and/or indium-zinc oxide (IZO).

8. The transparent non-volatile memory device of claim 1, wherein the active layer includes a transparent metal oxide layer.

9. The transparent non-volatile memory device of claim 8, wherein the transparent metal oxide layer includes titanium oxide and/or indium-titanium oxide.

10. A method of manufacturing a transparent non-volatile memory device comprising:
forming an active layer on a substrate;
forming a source and a drain spaced apart from each other on the active layer;
forming a gate insulating layer having quantum dots on the source, the drain, and the active layer; and
forming a gate on the gate insulating layer between the source and the drain,
wherein the quantum dots and the gate insulating layer are formed simultaneously.

11. The method of claim 10, wherein the gate insulating layer is formed by a plasma enhanced-chemical vapor deposition (PE-CVD) process.

12. The method of claim 11, wherein a silane gas and a nitrogen gas are used as a source gas and a reaction gas of the PE-CVD process, respectively.

13. The method of claim 12, wherein a mixture ratio of the silane gas to the nitrogen gas is within a range of about 1:1000 to about 1:4000 in the PE-CVD process.

14. The method of claim 11, wherein a silane gas and an ammonia gas are used as a source gas and a reaction gas of the PE-CVD process, respectively.

15. The method of claim 14, wherein a mixture ratio of the silane gas to the ammonia gas is within a range of about 1:1 to about 1:5 in the PE-CVD process.
